(19) United States
(12) Patent Application Publication
(10) Pub. No.: US 2017/0161887 A1
(43) Pub. Date: Jun. 8, 2017

(54) METHOD FOR EXTRACTING NON-PERIODICAL PATTERNS MASKED BY PERIODICAL PATTERNS, AND DEVICE IMPLEMENTING THE METHOD

(71) Applicant: FOGALE NANOTECH, Nîmes (FR)

(72) Inventor: Benoit THOUY, Montpellier (FR)

(21) Appl. No.: 15/325,684

(22) PCT Filed: Jul. 29, 2015
(86) PCT No.: PCT/EP2015/067343

§ 371 Date: Jan. 11, 2017

(30) Foreign Application Priority Data
Jul. 30, 2014 (FR) 1457369

(51) Int. Cl. G06T 7/00; H01L 23/544; G06T 5/00; G06T 5/10; G06K 9/00

(52) U.S. Cl. CPC G06T 7/0004; G06T 5/10; G06K 9/0051; G06T 5/002; H01L 23/544; G06T 2207/30148; G06T 2207/20048; H01L 2223/54406; H01L 2223/54433

(57) ABSTRACT

A method is provided for extracting information of interest from a measurement signal having a periodic interference pattern, which includes steps (i) of generating a filtering function representing the frequency components of the interference pattern, by implementing an analysis of an amplitude spectrum of the measurement signal based on morphological criteria, (ii) of applying the filtering function to the measurement signal so as to generate an interference signal constituted essentially by the interference pattern, and (iii) of calculating a filtered signal by carrying out a difference between the measurement signal and the interference signal.

The invention also relates to a device implementing the method.

### TECHNICAL FIELD

The present invention relates to a method for the processing of signals or images that makes it possible to extract non-periodic patterns masked by periodic patterns.

It relates more particularly to a method for the processing of images originating from microelectronics that makes it possible to distinguish aperiodic structures, such as characters, masked by periodic structures.

The field of the invention is more particularly, but not limitatively, that of the processing of signals or images for applications in the microelectronics industry.

### STATE OF THE PRIOR ART

The traceability of products within the semiconductor industry is a crucial task for quality control and for monitoring the products throughout the process of manufacturing and processing wafers.

To this end, an identification pattern such as a 1D or 2D barcode or alphanumeric characters is etched on the rear face of the wafers. An image of the identification pattern is produced by means of a camera. This image is then processed by a character recognition (OCR) or barcode reader program (for example) which decodes the information of the identification pattern and automatically provides the product's identifier.

In certain cases, in particular during the thinning of wafers to very small thicknesses (of the order of 100 μm), the product wafers are bonded to carrier wafers which are perforated in the form of a periodic matrix of perforations. In this case, the identification pattern present on the product wafer or optionally on the carrier wafer is only partially apparent because of the presence of the matrix of perforations.

In this case, in order to be able to read the identification pattern and, for example, to recognize its characters using OCR, it is necessary to process the image taken by the camera in order to filter out the matrix of holes and leave only the characters.

A known approach for solving this problem consists of spatially filtering out the holes that do not adjoin the fragments of characters. To this end, the segmentation of the fragments contained in the image is statistically filtered in order to leave only the fragments that do not correspond to holes. However, this approach is not entirely satisfactory because the holes that adjoin the characters are generally preserved, which locally deforms the characters and makes it much more difficult to recognize them. Moreover, this approach is very specific and linked to the shape of the holes, which prevents any generalization to the filtering of any periodic pattern.

Another known approach consists of using a wavelet transform to calculate frequency characteristics of the periodic pattern and consequently to filter the image. The difference between the filtered image (which preserves only the periodic pattern) and the initial image reveals the sought non-periodic elements. This approach is effective for a periodic pattern with a structural pattern which is relatively small compared with the size of the sought aperiodic elements (size of the support of the base wavelet) and which can be translated simply by statistics linked directly to the parameters of the wavelet used (for example, in the field of textile quality control: angle and spatial frequency).

More generally, the wafers during processing frequently comprise sets of periodic structures (transistors, etched patterns, etc.) within which it can be necessary to identify aperiodic elements (defects, etc.).

A subject of the present invention is to propose a method for the processing of signals or images which makes it possible to separate, in said signals or images, non-periodic patterns at least partially masked by periodic patterns and these periodic patterns.

Another subject of the present invention is to propose a method for the processing of signals or images which makes it possible to extract, from within said signals or images, non-periodic patterns which are at least partially masked by periodic patterns.

Another subject of the present invention is to propose a method for the processing of signals or images which makes it possible to distinguish, in images of wafers, non-periodic patterns which are at least partially masked by periodic patterns, and these periodic patterns.

Another subject of the present invention is to propose a method for the processing of signals or images which makes it possible to extract identification patterns etched or inscribed on wafers and at least partially masked by a periodic structure.

Another subject of the present invention is to propose a method for the processing of signals or images which makes it possible to separate identification patterns etched or inscribed on wafers and at least partially masked by a periodic structure.

### DISCLOSURE OF THE INVENTION

This objective is achieved with a method for extracting information of interest from a measurement signal comprising a periodic interference pattern, characterized in that it comprises steps of:
generating a filtering function representative of the frequency components of the interference pattern, by implementing an analysis of an amplitude spectrum of the measurement signal based on morphological criteria,
applying said filtering function to the measurement signal so as to generate an interference signal constituted essentially of the interference pattern,
calculating a filtered signal by carrying out a difference between the measurement signal and the interference signal.

The measurement signal can, non-limitatively, comprise:
a one-dimensional signal, for example in the form of a function or a curve with an amplitude f(x) as a function of a position or a time along an x axis. It can be, for example, an intensity profile;
a two-dimensional signal, for example in the form of an image with an intensity or a pixel value I(x, y) as a function of a position (x, y) in the plane of the image. It can be, for example, a greyscale image.

The periodic interference pattern can comprise a pattern, defined for example by variations in amplitude or intensity of the function f(x) or of the image I(x, y), which has a repetitive nature and the frequency spectrum of which has peaks.

In the implementation of the method according to the invention, the information of interest can be aperiodic or have periodicities. It is simply necessary that it does not generate significant peaks in the frequency spectrum of the signal or of the image. This condition is generally satisfied when the information of interest is localized (or has a restricted extent) in the spatial or time domain in relation to the interference pattern. If it is aperiodic it does not generate a significant peak in the spectral domain, and if it is localized it generates, at most, only very low-energy peaks, and therefore with an amplitude much lower than the amplitude of the frequency peaks due to the interference pattern.

The amplitude spectrum of the measurement signal can be defined, non-limitatively, as being the modulus of the frequency spectrum of the measurement signal.

The frequency spectrum can be obtained by performing a Fourier transform (one-dimensional 1D or two-dimensional 2D depending on the case) on the measurement signal.

This Fourier transform can be performed directly on the measurement signal.

Preferably, the Fourier transform can be performed on an apodized or windowed measurement signal. In this case, the measurement signal is multiplied by a 1D or 2D window function with progressive sides (for example triangular or of Gaussian shape) which makes it possible to avoid sudden transitions at the ends, which are sources of aliasing and spectral noise.

According to embodiments, the method according to the invention can comprise a step of generating the amplitude spectrum of the measurement signal with application of a dynamic range compression to the amplitude of the frequency spectrum of said measurement signal.

The amplitude spectrum can thus be obtained by applying a dynamic range compression function to the modulus of the frequency spectrum. This makes it possible to reduce the dynamic range and to improve the detection of peaks.

In particular it is possible to apply:
a logarithmic dynamic range compression law, and thus to obtain an amplitude spectrum with a logarithmic amplitude;
a polynomial law.

According to embodiments, the method according to the invention can comprise a step of multiplying a frequency spectrum of the measurement signal by the filtering function.

The filtering function is generated so as to be representative of the frequency components of the interference pattern. Therefore, in a way, it reproduces at least the essential spectral components of the interference pattern.

By multiplying the frequency spectrum of the measurement signal by this filtering function, the spectral components that are not due to the interference pattern are thus rejected.

This multiplication operation is preferably performed over the complete frequency spectrum (modulus and phase) of the measurement signal. It is performed symmetrically for the positive and negative frequencies so as to comply with the Hermitian symmetry of the frequency spectrum of the measurement signal.

An actual interference signal constituted essentially by the interference pattern can thus be obtained using an inverse Fourier transform.

Of course, it is also possible to calculate an inverse Fourier transform of the (frequency) filtering function and to calculate the interference signal by convolution of the measurement signal with the filtering impulse response obtained in this way.

According to embodiments, the method according to the invention can comprise a step of searching, in an amplitude spectrum of the measurement signal, for zones known as “h-maxima” zones corresponding respectively to sets of related points around local amplitude maximas satisfying a minimum height criterion with respect to the closest local amplitude minimas.

These h-maxima zones can be defined, for example, as the sets of points that can be connected to the local maximum by a non-descending path, i.e. along which the difference between two adjacent points in the direction of the local maximum always has the same sign.

The concept of local maximas can correspond to amplitude maximas. However, it should be noted that within the framework of the invention this concept can be interpreted differently, depending on the convention adopted. The local maximas can thus correspond, for example, to local extrema according to a predetermined convention of amplitude, sign and/or direction of variation.

The minimum height criterion can in particular be defined as a predetermined fraction of the maximum amplitude of the amplitude spectrum of the measurement signal.

The method according to the invention can comprise steps of:
generating a shifted amplitude spectrum corresponding to the amplitude spectrum of the measurement signal shifted towards the lower amplitudes of a quantity corresponding to the minimum height criterion and bounded at zero,
geodesic reconstruction of said shifted amplitude spectrum in the amplitude spectrum of the measurement signal, so as to obtain a clipped amplitude spectrum corresponding to the amplitude spectrum of the measurement signal clipped of the quantity corresponding to the minimum height criterion in the h-maxima zones,
calculating an amplitude spectrum of the h-maxima zones by difference between the amplitude spectrum of the measurement signal and the clipped amplitude spectrum.
generating a filtering function with zero values outside the h-maxima zones, and a constant non-zero value in said h-maxima zones.

According to embodiments, the method according to the invention can comprise steps of:
localizing the local minimas of the amplitude spectrum of the measurement signal,
geodesic reconstruction of said local minimas in the amplitude spectrum of the measurement signal, so as to obtain a base amplitude spectrum representing the amplitude at the base of the peaks of the amplitude spectrum of the measurement signal,
calculating an amplitude spectrum of the peaks by difference between the amplitude spectrum of the measurement signal and the base amplitude spectrum.

Calculation of the amplitude spectrum of the peaks can also comprise a step of applying a threshold, the values below said threshold being set to zero.

The method according to the invention can also comprise a step of generating a filtering function from the amplitude spectrum of the peaks, with a constant non-zero value in the zones of the amplitude spectrum of the peaks with an amplitude above a predetermined binarization threshold, and a zero value elsewhere.

According to embodiments, the method according to the invention can also comprise a step of filling shallow local minimas with:
a generation of an inverted amplitude spectrum corresponding to an amplitude symmetry of the amplitude spectrum of the measurement signal,
a generation of an inverted and shifted amplitude spectrum, by shifting said inverted amplitude spectrum towards the low amplitudes of a quantity representative of a depth of minimas to be filled,
a geodesic reconstruction of said inverted and shifted amplitude spectrum in said inverted amplitude spectrum.

According to embodiments, the method according to the invention can comprise steps of:
generating a reference filtering function representative of the frequency components of the interference pattern, by implementing an analysis of an amplitude spectrum of a reference signal comprising essentially the reference pattern,
identifying maximas of the amplitude spectrum of the measurement signal,
generating a filtering function by adjustment of the reference filtering function over the identified maximas of the amplitude spectrum of the measurement signal.

The adjustment can be performed in particular as a magnification or a homothety, and/or a rotation.

According to preferred embodiments, the method according to the invention can be implemented with a measurement signal comprising an image of one of the following types: image of at least one part of a wafer, image of at least one part of an assembly of wafers, image of at least one part of a wafer fixed on a wafer carrier.

It can comprise a step of extracting information of interest of one of the following forms: identification information, alphanumeric characters, written signs, 1D barcode, 2D barcode, QR code.

According to embodiments, the invention can thus relate to a method for extracting information of interest, in particular information of interest of one of the following forms: identification information, alphanumeric characters, written signs, 1D barcode, 2D barcode, QR code, from a measurement signal, in particular a measurement signal comprising an image of one of the following types: image of at least one part of a wafer, image of at least one part of an assembly of wafers, image of at least one part of a wafer fixed on a wafer carrier, which measurement signal comprises a periodic interference pattern.

A method is also proposed for extracting identification information from a wafer at least partially masked by a wafer carrier with a periodic structure of holes, comprising steps of:
acquiring an image comprising the identification information,
extracting said identification information by implementing the steps of the method according to the invention.

According to embodiments, the method according to the invention can comprise a step of extracting information of interest such as one or more isolated or singular elements, for example originating from a manufacturing process (tracks, vias, waveguides, etc.) or corresponding to defects (cracks, etc.), from an image comprising a periodic interference pattern or a repetitive structure such as a set of transistors, of etched components, a diffraction grating.

According to another aspect, a device is proposed for extracting information of interest from a measurement signal comprising a periodic interference pattern, comprising imaging means for acquiring a measurement signal in the form of an image, and calculation means arranged to:
generate a filtering function representative of the frequency components of the interference pattern, by implementing an analysis of an amplitude spectrum of the measurement signal based on morphological criteria,
apply said filtering function to the measurement signal so as to generate an interference signal constituted essentially by the interference pattern,
calculate a filtered signal by carrying out a difference between the measurement signal and the interference signal.

The method according to the invention is therefore based on a principle which consists of subtracting, from the signal or the original measurement image, a filtered version of this signal or of this image which contains essentially the periodic interference pattern.

According to an advantageous aspect of the invention, the filtering is carried out in the frequency domain, preferably as a whole over all of the signal or image.

By selecting the peaks in the frequency spectrum, the periodic pattern can be taken in its entirety, and the filtering is then effective whatever the complexity of this pattern.

After subtraction from the original image, the non-periodic parts, with the information of interest (for example alphanumeric characters), therefore remain.

It is to be noted that in the different embodiments presented, the filtering function is generated by implementing an analysis of the amplitude spectrum of the measurement signal based on morphological criteria.

Thus, in its different embodiments, the invention implements tools originating from mathematical morphology techniques or more generally shape analysis techniques.

The method according to the invention also has the advantage that it does not require knowledge of the characteristics of the texture or the structure of the periodic pattern.

The method according to the invention can, of course, be implemented for other applications in all fields.

There may be mentioned for example, in the field of textiles, the location of defects in wefts.

### DESCRIPTION OF THE FIGURES AND EMBODIMENTS

Other advantages and characteristics of the invention will become apparent on reading the detailed description of implementations and embodiments which are in no way limitative, and from the following attached drawings:

FIG. 1 illustrates an embodiment of the method according to the invention for identifying references of wafers bonded to perforated carriers,

FIG. 2 illustrates a general block diagram of the method according to the invention,

FIG. 3 illustrates the generation of the filtering function according to a first embodiment of the invention,

FIG. 4 illustrates the generation of the filtering function according to a second embodiment of the invention,

FIG. 5 illustrates a variant that can be applied to the first and second embodiments of the invention,

FIG. 6 illustrates results obtained with the method according to the invention, a first initial image in FIG. 6a, the corresponding filtered image in FIG. 6b, a second initial image in FIG. 6c and the corresponding filtered image in FIG. 6d.

It is well understood that the embodiments that will be described hereinafter are in no way limitative. Variants of the invention can in particular be envisaged comprising only a selection of the characteristics or steps described below in isolation from the other described characteristics or steps, if this selection of characteristics or steps is sufficient to confer a technical advantage or to differentiate the invention with respect to the state of the prior art.

In particular, all the described variants and embodiments can be combined if there is no objection to this combination from a technical point of view.

In the figures, the components common to several figures retain the same references.

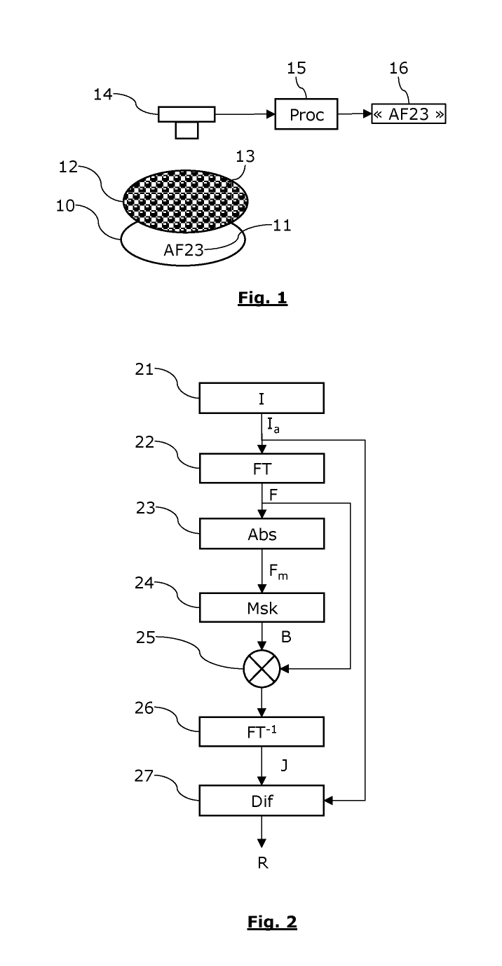

With reference to FIG. 1, an embodiment of the invention in a microelectronics process will be described, for “reading” or identifying identification codes on wafers intended to be used for the production of integrated circuits.

These wafers 10 are provided with an identification code 11, in particular with the aim of traceability during the steps of the process. In the example presented, this identification code 11 comprises alphanumeric characters.

In order to perform thinning operations in particular, the wafers 10 are bonded to glass carriers 12. These carriers 12 are perforated in the form of a periodic pattern 13 of perforations. In this case, the identification pattern 11 present on the wafer 10 under the carrier 12 (or optionally on the carrier 12 itself) is only partially apparent because of the presence of the periodic pattern 13 of perforations. This identification pattern 11 is therefore partially masked by the carrier 12, either because it is partially covered by the carrier 12 or because it is only partially printed or etched on the carrier 12 in its filled zones.

In order to identify a wafer 10, an imaging device can be used which comprises a camera 14 (or any other imaging means) and calculation means 15 for example based on a microprocessor or a computer:
an image of the identification pattern 11 is acquired with the camera 14;
a processing of the image is performed in order to extract the identification pattern 11 from it (segmentation);
the information of the identification pattern 11 is extracted in order to obtain the identifier 16 of the wafer 10, for example by means of character recognition (OCR) software or barcode reader software, as appropriate.

In this case, in order to be able to read the identification pattern 11 and, for example, to recognize its characters using OCR, it is necessary to process the image taken by the camera 14 in order to filter out the periodic pattern 13 and essentially leave only the elements of the identification pattern 11 (the characters) visible.

The subject of the method according to the invention is precisely this. In the embodiment presented, it is implemented in calculation means 15 arranged for this purpose.

With reference to FIG. 2, the method according to the invention therefore comprises a step 21 of acquiring or obtaining a measurement signal in the form of an initial image I, which comprises information of interest 11 (the identification code 11) partially masked by a periodic interference pattern 13 (the periodic pattern 13).

The initial image I can be acquired directly by the camera 14, or originate from a storage means (hard disk, memory, etc.).

Non-limitatively, an initial image I in which the identification code 11 appears dark on a light background, and where the periodic pattern 13 which has the form of a periodic matrix of holes 13 is also dark, is considered in the embodiment presented. The level of intensity of the holes of the periodic pattern 13 can be equivalent to that of the fragments of characters of the identification code 13, which prevents any spatial segmentation by greyscale according to known methods.

It is to be noted that in the case of an initial image I with a white identification pattern or white characters 11 on a black background it is sufficient to take a negative of this initial image I at the start in order to be in the configuration described previously.

An apodized image Iₐ is then constructed, which corresponds to the initial image I in which the intensity of the pixels on a margin with width A is reduced in order to tend towards a constant value (for example 0) at the edge of the image. The apodization function can be, for example, a Gaussian function, or more simply a linear decrease. The apodized image Iₐ is obtained by multiplying the initial image I by the apodization function.

The benefit of this apodization step (which, however, is not essential) is to limit the edge effects during the calculation of the Fourier transform: as the digital Fourier transform assumes a periodic image, any discontinuity between the left-hand and right-hand edges (and top and bottom) of the image leads to the appearance of virtual frequencies due to an aliasing effect. It is therefore preferable to use an apodization function which has a spectrum limited essentially to low frequencies.

The method according to the invention also comprises a step 22 of calculating the frequency spectrum F of the initial image I. This frequency spectrum F is obtained by means of a two-dimensional digital Fourier transform calculation.

As the initial image I is in effective values, the frequency spectrum F is therefore a complex image with Hermitian symmetry.

The method according to the invention then comprises a step 23 of calculating an amplitude spectrum Fₘ of the initial image I. In the embodiment presented, this amplitude spectrum Fₘ corresponds to the logarithm of the norm or of the modulus of the frequency spectrum F:

Fₘ=log(abs(F)).

The benefit of taking the logarithm of the modulus of the frequency spectrum F and not simply its modulus is that this introduces a compression of the dynamic range of the amplitude spectrum Fₘ. In general, the spectral intensity in the frequency spectrum F around the zero frequency is several orders of magnitude above that of the high frequencies: the logarithmic compression makes it possible to further reduce the extent of the dynamic range.

The method according to the invention also comprises a step 24 of generating a filtering function representative of the frequency components of the periodic interference pattern 13.

This filtering function is obtained by implementing an analysis of the amplitude spectrum Fₘ on the basis of morphological criteria. Several variants of this analysis are possible within the framework of the invention. They will be described below.

In general:
the peaks of the amplitude spectrum Fₘ which correspond to the characteristic frequencies of the periodic pattern 13 are selected by implementing morphological criteria and/or methods originating from mathematical morphology; and
a binary mask B which precisely represents the selection in the amplitude spectrum Fₘ of the frequency peaks corresponding to the characteristic frequencies of the periodic pattern 13 is created.

This binary mask comprises non-zero values (for example one) for the frequencies corresponding to the zones of the selected frequency peaks and zero values (zero) for the other frequencies.

The method according to the invention also comprises a step 25 of masking the frequency spectrum F with the binary mask B in order to generate a filtered frequency spectrum F_{B}. This masking can be carried out for example by an operation multiplying the frequency spectrum F by the binary mask B:

F_{B}=F×B.

Thus, any complex element of F which does not belong to B is set to zero in F_{B}, and otherwise is retained.

This masking operation is carried out so as to retain the Hermitian symmetry of the frequency spectrum F in the filtered frequency spectrum F_{B}.

To this end, it is possible, for example:
to generate an even mask B, i.e. which has one and the same value for each frequency and for the corresponding frequency with the opposite sign;
or, more generally, to generate a mask B corresponding to the part of the spectral plane in which the FFT is calculated.

The method according to the invention also comprises a step 26 of calculating the two-dimensional inverse Fourier transform of the filtered frequency spectrum F_{B}. An image known as the “interference” image J is thus obtained which is real if the Hermitian symmetry of the frequency spectrum F was respected during the masking.

The interference image J corresponds to the initial image I (or more precisely the apodized initial image Iₐ) filtered of all the elements of I that are non-periodic (or have low spectral energy). The interference image J therefore comprises essentially the periodic interference pattern 13. This interference image J also retains the variations in illumination of the initial image I because the very low frequencies belong to the peak the vertex of which is the zero frequency.

The method according to the invention also comprises a step 27 of calculating a filtered image R, corresponding to a pixel-by-pixel difference between the interference image J and the initial image I (or more precisely the apodized initial image Iₐ):

R=J−Iₐ.

In this filtered image R, the non-periodic elements of the initial image I appear with a high intensity, the rest being dark. The negative intensities are thresholded to zero. They appear in particular because pixels of the interference image J can be negative. This is explained by the fact that the energy of the initial image I is retained while certain frequencies are suppressed, creating a larger dynamic range.

Thus, in the filtered image R, the fragments of characters 11 appear clear and brilliant, or at least in a clearly more discernible manner than in the measurement image I.

Known segmentation and character recognition (OCR) techniques can then be implemented much more effectively in order to extract the information of the identification pattern 11 and obtain the identifier 16 of the wafer 10.

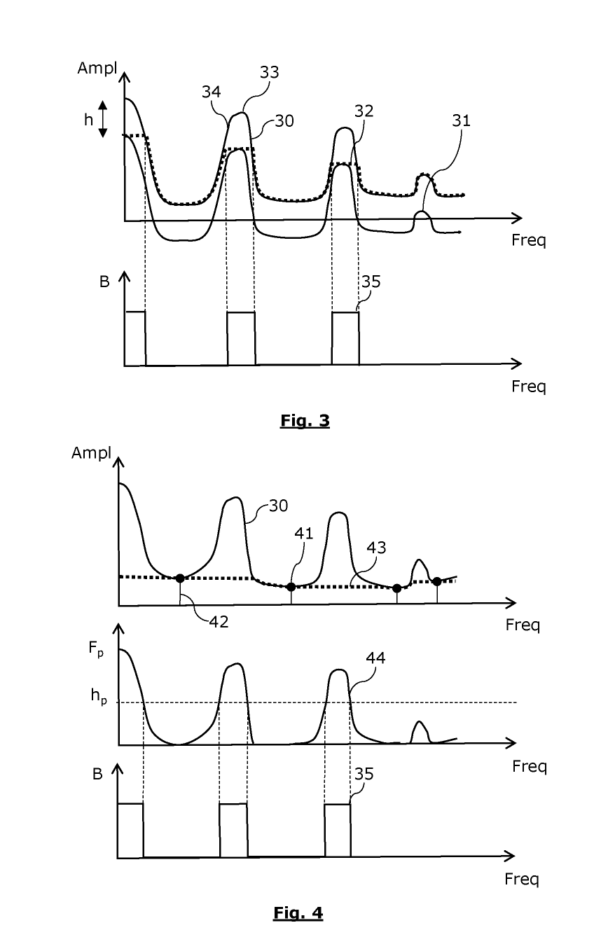

With reference to FIG. 3, a first method of generating the binary mask B will now be described in detail.

For reasons of clarity, this method of generating the binary mask B is illustrated by one-dimensional curves. Such curves can be, for example, representative of a profile along a frequency axis of the amplitude spectrum Fₘ.

It is to be noted that they can also be illustrative of an implementation of the method according to the invention on a one-dimensional measurement signal.

Of course, the operations which are described below can be applied both to one-dimensional measurement signals and to two-dimensional images.

Firstly, the zones 34 known as “h-maxima” zones are sought in the amplitude spectrum Fₘ (curve 30). These zones 34, also called h-maxima according to the terminology of mathematical morphology, correspond respectively to sets of related points around local amplitude maximas 33 which satisfy a minimum height criterion h with respect to the closest local amplitude minimas.

Preferably, the minimum height criterion h is defined as being a fraction of the maximum amplitude of the amplitude spectrum Fₘ. For example, h can be set at 25% of this maximum amplitude.

In order to determine these h-maxima zones, a shifted amplitude spectrum F_{d} (curve 31) is generated which corresponds to the amplitude spectrum Fₘ shifted in terms of amplitude, towards the lower amplitudes, by h:

F_{d}=Fₘ−h.

A clipped amplitude spectrum Fₑ is then calculated by performing a geodesic reconstruction of the shifted amplitude spectrum F_{d} in the amplitude spectrum Fₘ.

This geodesic reconstruction is defined as a repetition until the amplitude spectrum Fₘ of a dilation of the shifted amplitude spectrum F_{d} with a plane structuring element g parallel to the plane of the frequencies (or one-dimensional parallel to the axis of the frequencies in the case of one-dimensional geodesic reconstruction) is reached.

Mathematically, this geodesic reconstruction can be written as follows:

E_{g}^{Fm}(F_{d})=sup_{n≧0}{(δ_{g}^{Fm})ⁿ(F_{d})},

where the index n indicates an iteration and δ_{g}^{Fm}(F_{d}) is the geodesic dilation of F_{d} in Fₘ with the structuring element g. Then:

δ_{g}^{Fm}(F_{d})=δ_{g}(F_{d})̂Fₘ,

where δ₉(F_{d}) is the dilation of F_{d} by the structuring element g and the operator ̂ (inf) returns the minorant or the largest of the minorants.

Graphically, the result of the geodesic reconstruction of the shifted amplitude spectrum F_{d} in the amplitude spectrum Fₘ (corresponding to the clipped amplitude spectrum Fₑ) is illustrated by the curve 32. This clipped amplitude spectrum Fₑ curve therefore corresponds to the amplitude spectrum Fₘ clipped of the h-maxima zones 34 (i.e. clipped at amplitudes lower of h than the amplitude of the local maximas 33 which satisfy the criterion of the h-maximas).

An amplitude spectrum of the h-maxima zones Fₘₕ is then calculated by carrying out the difference between the amplitude spectrum Fₘ and the clipped amplitude spectrum Fₑ corresponding to the geodesic reconstruction

E_{g}^{Fm}(F_{d}).

Then, the amplitude spectrum of the h-maxima zones Fₘₕ is binarized with respect to a predefined binarization threshold.

A mask B with non-zero values (for example one) in the zones 35 above the binarization threshold and zero values in the zones below the binarization threshold is thus obtained. If this binarization threshold is set at zero, as illustrated in FIG. 3, the non-zero zones 35 of the mask B correspond to the h-maximas 34.

In this way, a mask B that is very representative of the spectral zones in which the energy due to the periodic pattern 13 is significant is obtained. It is thus possible to take account not only of the position of the frequency peaks but also of their width or their extent. This makes it possible to reconstruct the periodic pattern 13 very accurately and very faithfully.

With reference to FIG. 4, a second method of generating the binary mask B will now be described in detail.

As before, for reasons of clarity, this method of generating the binary mask B is illustrated by one-dimensional curves. Such curves can be, for example, representative of a profile along a frequency axis of the amplitude spectrum Fₘ.

It is to be noted that they can also be illustrative of an implementation of the method according to the invention on a one-dimensional measurement signal.

Of course, the operations which are described below can be applied both to one-dimensional measurement signals and to two-dimensional images.

Firstly, the local minimas 41 are sought in the amplitude spectrum Fₘ (curve 30).

A spectrum of the minimas Fₘᵢₙ (curve 42) is thus defined which has the value of the local minimas 41 at the corresponding frequencies and a zero value at the other frequencies.

A base amplitude spectrum F_{b} is then calculated by performing a geodesic reconstruction of the spectrum of the minimas Fₘᵢₙ in the amplitude spectrum Fₘ.

As before, the geodesic reconstruction is defined as a repetition until the amplitude spectrum Fₘ of a dilation of the spectrum of the minimas Fₘᵢₙ with a plane structuring element g parallel to the plane of the frequencies (or one-dimensional parallel to the axis of the frequencies in the case of one-dimensional geodesic reconstruction) is reached.

Mathematically, this geodesic reconstruction can be written as follows:

E_{g}^{Fm}(Fₘᵢₙ)=sup_{n≧0}{(δ_{g}^{Fm})ⁿ(Fₘᵢₙ)},

where the index n indicates an iteration and δ_{g}^{Fm}(Fₘᵢₙ) is the geodesic dilation of Fₘᵢₙ in Fₘ with the structuring element g. Then:

δ_{g}^{Fm}(Fₘᵢₙ)=δ_{g}(Fₘᵢₙ)̂Fₘ,

where δ_{g}(Fₘᵢₙ) is the dilation of F_{d} by the structuring element g and the operator ̂ (inf) returns the largest of the minorants.

Graphically, the result of the geodesic reconstruction of the spectrum of the minimas Fₘᵢₙ in the amplitude spectrum Fₘ (corresponding to the base amplitude spectrum F_{b}) is illustrated by the curve 43. This base amplitude spectrum F_{b} is thus representative of the continuous background of the amplitude spectrum Fₘ.

An amplitude spectrum of the peaks Fₚ is then calculated by difference between the amplitude spectrum Fₘ and the base amplitude spectrum F_{b}. This amplitude spectrum of the peaks Fₚ is illustrated by the curve 44.

Then, the amplitude spectrum of the peaks Fₚ is binarized with respect to a binarization threshold hₚ. This binarization threshold hₚ can, for example, be set as a fraction of the maximum amplitude of the amplitude spectrum of the peaks Fₚ. In the embodiment illustrated in FIG. 4, this binarization threshold hₚ is set at 50% of the maximum amplitude of the amplitude spectrum of the peaks Fₚ, so as to reject the low amplitude peaks.

A mask B with non-zero values (for example one) in the zones 35 above the binarization threshold hₚ and zero values in the zones below the binarization threshold is thus obtained.

In this way, a mask B that is very representative of the spectral zones in which the energy due to the periodic pattern 13 is significant is obtained. It is thus possible to take account not only of the position of the frequency peaks but also of their width or their range. This makes it possible to reconstruct the periodic pattern 13 very accurately and very faithfully.

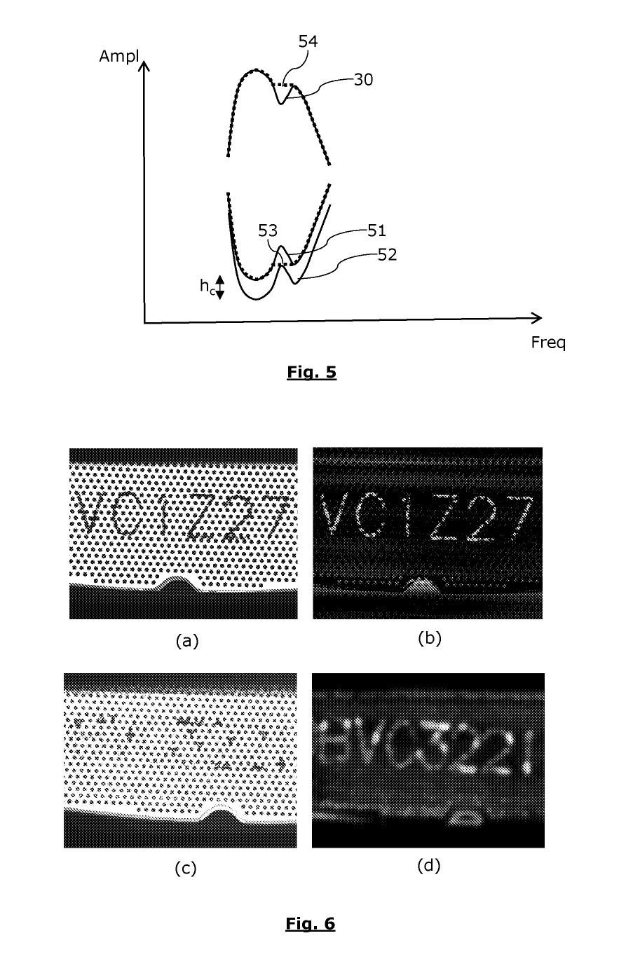

With reference to FIG. 5, according to a variant, the method according to the invention can comprise an additional step of filling of the shallow local minimas of the amplitude spectrum Fₘ. This step can be implemented with the first method or with the second method of generating the binary mask B.

The objective of this variant is to eliminate the artifacts which can appear when the amplitude spectrum Fₘ comprises very close, partially merged peaks.

According to this variant, the binary mask B is generated according to the methods described with reference to FIG. 3 and FIG. 4 from a filled amplitude spectrum F_{mc} instead of using the amplitude spectrum Fₘ.

The filled amplitude spectrum F_{mc} is calculated as follows:
an inverted amplitude spectrum Fₘᵢ (curve 51) corresponding to an amplitude symmetry of the amplitude spectrum Fₘ (curve 30) is generated;
then an inverted and shifted amplitude spectrum F_{mid} is generated by shifting the inverted amplitude spectrum Fₘᵢ towards the low amplitudes by a quantity hₑ representing the depth of minimas to be filled;
then a filled inverted amplitude spectrum F_{mc}i (curve 53) is calculated by performing a geodesic reconstruction of the inverted and shifted amplitude spectrum F_{mid} in the inverted amplitude spectrum Fₘᵢ:

F_{mci}=E_{g}^{Fmi}(F_{fmid})=sup_{n≧0}{(δ_{g}^{Fmi})ⁿ(F_{mid})};
finally, the filled amplitude spectrum F_{mc} (curve 54) is obtained by performing an amplitude symmetry on the inverted filled amplitude spectrum F_{mci}.

As illustrated in FIG. 5, the thus-obtained filled amplitude spectrum F_{mc} corresponds to the amplitude spectrum Fₘ in which the minimas with a depth up to the quantity hₑ (or, in other words, the h-minimas with a depth parameter between 0 and h_{c}) are filled. It is to be noted that the h-minimas with a depth greater than hₑ are not affected.

A third method of generating the binary mask B will now be described in detail.

In this embodiment, a predetermined reference filtering function, in the form of a reference mask Bᵣ, is used.

This reference mask Bᵣ is a binary mask representing the frequency components of the periodic interference pattern 13. It is determined from a reference image.

This reference image can be obtained in different ways. It can be, for example:
a theoretical image, generated from a modelling of the periodic pattern 13;
an image obtained by imaging, with a camera, a zone in which there is essentially only the periodic pattern 13.

The reference binary mask Bᵣ is therefore generated from the reference image. To this end, one of the methods described previously with reference to FIG. 3, FIG. 4 and FIG. 5 can preferably be used.

In this way, a reference binary mask Bᵣ that is very representative of the spectral zones in which the energy due to the periodic pattern 13 is significant is obtained, which takes account not only of the position of the frequency peaks but also of their width or their range.

A reference binary mask Bᵣ can thus be calculated once and for all.

The use of the reference mask Bᵣ to extract information of interest 11 that is partially masked by a periodic interference pattern 13 of an initial image I will now be described.

It is assumed, of course, that the periodic pattern 13 of the image I is similar to that which was used to generate the reference mask Bᵣ.

The imaging conditions for this periodic pattern 13 can be different between the reference image and the initial image I. In this case, at least initially (without deformations of the imaged surface), these differences in imaging conditions can be modelled essentially by at least one of the following transformations: a translation, a rotation and a magnification or a homothety.

In this embodiment of the invention, as before, the initial image I can be acquired directly by the camera 14, or originate from a storage means (hard disk, memory, etc.).

It is then processed according to the general method described previously with reference to FIG. 1.

In order to generate the binary mask B:
an amplitude spectrum Fₘ is calculated as before,
the main local maximas of this amplitude spectrum Fₘ are detected. This detection can be performed with a simple algorithm since it is possible to limit it to the detection of the position of the most significant frequency peaks (essentially due to the periodic pattern 13).
an adjustment in the frequency domain of the reference binary mask Bᵣ is then performed in order that it is best adapted or corresponds best to the main local maximas of the amplitude spectrum Fₘ. Advantageously, this adjustment can be performed with a limited set of transformations since it is possible to limit it to the transformations which relate to the modulus of the Fourier transform: homotheties along the frequency axis or axes with the zero frequency for origin and/or rotation about the zero frequency. In particular, it is not necessary to take account of the spatial translations of the initial image I which only affect the phase of the Fourier transform.

A deformed version T(Bᵣ) of the reference binary mask Bᵣ which corresponds to the sought binary mask B is thus obtained:

B=T(Bᵣ).

The transformation function T comprises a transformation or a combination of transformations from: one or more homotheties along the frequency axis or axes with the zero frequency for origin and/or a rotation about the zero frequency.

The adjustment can be performed according to known methods, for example by minimizing an error function in the least-squares sense.

FIG. 6 illustrates results obtained with the method according to the invention. The presented images are details of processed images.

FIG. 6a and FIG. 6c show initial images I obtained with a camera 14 on wafers 10 bonded to glass carriers 12, perforated in the form of a periodic pattern 13 of perforations. As can be seen, the identification pattern 11 present (an alphanumeric inscription) is difficult to read on these images, in particular on that of FIG. 6c.

FIG. 6b and FIG. 6d show filtered images R obtained with the method according to the invention in the embodiment thereof described with reference to FIG. 3, and applied respectively to the initial images I of FIG. 6a and FIG. 6c.

In FIG. 6d, an anisotropic filtering has also been applied.

As can be seen, in particular in FIG. 6d, the method according to the invention greatly improves the readability of the identification pattern 11, both for the human eye and for processing with a character recognition (OCR) algorithm.

Of course, the invention is not limited to the examples which have just been described and numerous adjustments can be made to these examples without exceeding the scope of the invention.

1. A method for extracting information of interest from a measurement signal comprising a periodic interference pattern, comprising steps of:
generating a filtering function representative of the frequency components of the interference pattern, by implementing an analysis of an amplitude spectrum of the measurement signal based on morphological criteria;
applying said filtering function to the measurement signal so as to generate an interference signal constituted essentially by the interference pattern; and
calculating a filtered signal by carrying out a difference between the measurement signal and the interference signal.

2. The method according to claim 1, which comprises a step of generating the amplitude spectrum of the measurement signal with application of a dynamic range compression to the amplitude of the frequency spectrum of said measurement signal.

3. The method according to claim 1, which comprises a step of multiplying the frequency spectrum of the measurement signal by the filtering function.

4. The method according to claim 1, which comprises a step of searching, in the amplitude spectrum of the measurement signal, for zones known as “h-maxima” zones corresponding respectively to sets of related points around local amplitude maximas satisfying a minimum height criterion with respect to the closest local amplitude minimas.

5. The method according to claim 4, in which the minimum height criterion is defined as a predetermined fraction of the maximum amplitude of the amplitude spectrum of the measurement signal.

6. The method according to claim 4, which comprises steps of:
generating a shifted amplitude spectrum corresponding to the amplitude spectrum of the measurement signal shifted towards the lower amplitudes by a quantity corresponding to the minimum height criterion and bounded at zero;
geodesic reconstruction of said shifted amplitude spectrum in the amplitude spectrum of the measurement signal, so as to obtain a clipped amplitude spectrum corresponding to the amplitude spectrum of the measurement signal clipped of the quantity corresponding to the minimum height criterion in the h-maxima zones; and
calculating an amplitude spectrum of the h-maxima zones by difference between the amplitude spectrum of the measurement signal and the clipped amplitude spectrum.

7. The method according to claim 4, which comprises a step of generating a filtering function with zero values outside the h-maxima zones, and a constant non-zero value in said h-maxima zones.

8. The method according to claim 1, which comprises steps of:
localizing the local minimas of the amplitude spectrum of the measurement signal;
geodesic reconstruction of said local minimas in the amplitude spectrum of the measurement signal so as to obtain a base amplitude spectrum representative of the amplitude at the base of the peaks of the amplitude spectrum of the measurement signal; and
calculating an amplitude spectrum of the peaks by difference between the amplitude spectrum of the measurement signal and the base amplitude spectrum.

9. The method according to claim 8, which comprises a step of generating a filtering function from the amplitude spectrum of the peaks, with a constant non-zero value in the zones of the amplitude spectrum of the peaks with an amplitude above a predetermined binarization threshold, and a zero value elsewhere.

10. The method according to claim 1, which also comprises a step of filling shallow local minimas with:
a generation of an inverted amplitude spectrum corresponding to an amplitude symmetry of the amplitude spectrum of the measurement signal;
a generation of an inverted and shifted amplitude spectrum, by shifting said inverted amplitude spectrum towards the low amplitudes by a quantity representing a depth of minimas to be filled, and
a geodesic reconstruction of said inverted and shifted amplitude spectrum in said inverted amplitude spectrum.

11. The method according to claim 1, which comprises steps of:
generating a reference filtering function representative of the frequency components of the interference pattern, by implementing an analysis of an amplitude spectrum of a reference signal comprising essentially the reference pattern;
identifying maximas of the amplitude spectrum of the measurement signal; and
generating a filtering function by adjustment of the reference filtering function over the identified maximas of the amplitude spectrum of the measurement signal.

12. The method according to claim 1, which is implemented with a measurement signal comprising an image of one of the following types: image of at least one part of a wafer, image of at least one part of an assembly of wafers, image of at least one part of a wafer fixed on a wafer carrier.

13. The method according to claim 12, which comprises a step of extracting information of interest of one of the following forms: identification information, alphanumeric characters, written signs, 1D barcode, 2D barcode, QR code.

14. A method for extracting identification information of a wafer at least partially masked by a wafer carrier with a structure of periodic holes, comprising steps of:
acquiring an image comprising the identification information; and
extracting said identification information by implementing the steps of the method according to claim 1.

15. A device for extracting information of interest from a measurement signal comprising a periodic interference pattern comprising:
imaging means for acquiring a measurement signal in the form of an image, and
calculation means arranged to:
generate a filtering function representing the frequency components of the interference pattern, by implementing an analysis of an amplitude spectrum of the measurement signal based on morphological criteria;
apply said filtering function to the measurement signal so as to generate an interference signal constituted essentially by the interference pattern; and
calculate a filtered signal by carrying out a difference between the measurement signal and the interference signal.
